(19) United States
(12) Patent Application Publication
(10) Pub. No.: US 2025/0275345 A1
(43) Pub. Date: Aug. 28, 2025

(54) DISPLAY DEVICE

(71) Applicant: LG Display Co., Ltd., Seoul (KR)

(72) Inventors: EunYoung PARK, Seoul (KR); HoSung KIM, Suwon-si (KR)

(21) Appl. No.: 19/002,280

(22) Filed: Dec. 26, 2024

(30) Foreign Application Priority Data
Feb. 26, 2024 (KR) 10-2024-0027424

(51) Int. Cl. H10H 29/85; H10H 29/39; H10H 29/853

(52) U.S. Cl. CPC H10H 29/8582; H10H 29/39; H10H 29/853

(57) ABSTRACT

The present disclosure relates to a display device. A display device of one embodiment is provided with at least one sensor area. The display device includes a substrate. The display device includes a thin film transistor on the substrate. The display device includes a planarization layer disposed to cover the thin film transistor. The display device includes a light emitting diode on the planarization layer. The light emitting diode including a first electrode, an emission layer on the first electrode, and a second electrode on the emission layer. The display device includes a bank configured to expose at least part of the first electrode and disposed on the planarization layer. The display device includes a sensor part disposed on a back surface of the substrate in the sensor area. The display device includes a heat dissipation panel disposed between the substrate and the first electrode.

### CROSS-REFERENCE TO RELATED APPLICATIONS

This application claims the priority of Korean Patent Application No. 10-2024-0027424 filed on Feb. 26, 2024, in the Korean Intellectual Property Office, the disclosure of which is incorporated herein by reference.

### BACKGROUND

### Technical Field

The present disclosure relates to a display device, and particularly, a display device that secures improvement in reflectance and visual sensing of reflection.

### Description of the Related Art

In the information era, the field of displays displaying electric information signals visually has been rapidly progressed, and in response, various types of display devices that ensure thinness, lightweight and low power consumption have been developed.

Additionally, a display device may be provided with a sensor to have an image capturing function and a variety of sensing functions. Specifically, a display device such as a laptop or a mobile phone may be provided with a biometric sensor such as a fingerprint recognition sensor currently, to have a security function.

The above sensors are conventionally inserted into a through hole formed in a non-display area.

### BRIEF SUMMARY

When the sensors are inserted into a through hole formed in the non-display area of a display device, the bezel area increases, reducing the surface area of a display area and causing design restrictions. To address this issue, various designs are proposed where a sensor part is provided on the back surface of the substrate in the display area, without reducing the surface area of the display area. In the case where the above-described sensor is provided on the back surface of the substrate in the display area, heat generated from the sensor affects an organic light emitting diode, degrading the organic light emitting diode. In particular, the sensor part comprises Tx electrodes connecting to a Tx driver, and Rx electrodes connecting to an Rx driver, and at portions where the Tx electrodes cross the Rx electrodes, a sensor capacitor is formed, so that a large number of lines are integrated in a single circuit, causing more amounts of heat. At this time, heat generated from the sensor part is transferred to the light emitting diode, causing damage to the light emitting diode.

In the case where the temperature of an organic light emitting diode, as an element sensitive to temperature, remains at 130° C., the properties of the diode are degraded as time passes, and further, display quality deteriorates.

Various embodiments of the present disclosure provide a display device that prevents the degradation of the light emitting diode, caused by heat generated from the senor part, thereby providing a highly reliable display device.

Technical benefits of the present disclosure are not limited to the above-mentioned benefits, and other benefits, which are not mentioned above, can be clearly understood by those skilled in the art from the following descriptions.

A display device of one embodiment is provided with at least one sensor area, and comprises a substrate, a thin film transistor disposed on the substrate; a planarization layer disposed to cover the thin film transistor; a light emitting diode disposed on the planarization layer, and configured to comprise a first electrode, an emission layer disposed on the first electrode and a second electrode disposed on the emission layer; a bank configured to expose at least part of the first electrode and disposed on the planarization layer; a sensor part disposed on a back surface of the substrate in the sensor area; and a heat dissipation panel disposed between the substrate and the first electrode.

Other detailed matters of the exemplary embodiments are included in the detailed description and the drawings.

In one embodiment of the present disclosure, a highly reliable display device that blocks the transfer of heat generated from a sensor to the light emitting diode, thereby preventing degradation of the light emitting diode and secures high reliability.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a display device of one embodiment;

FIG. 2 is an enlarged view of a portion of a sensor area of FIG. 1;

FIG. 3 is a cross-sectional view of a portion of the sensor area in the display device of one embodiment;

FIGS. 4A-4C are views for describing a process of forming a heat dissipation panel in the display device of one embodiment;

FIG. 5 is a cross-sectional view of a sensor area in a display device of another embodiment;

FIGS. 6A-6F are views for describing a process of forming a heat dissipation panel in the display device of another embodiment;

FIG. 7 is a cross-sectional view of a sensor area in a display device of another embodiment;

FIG. 8 is a cross-sectional view of a sensor area in a display device of another embodiment; and

FIG. 9 is a cross-sectional view of a sensor area in a display device of yet another embodiment.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

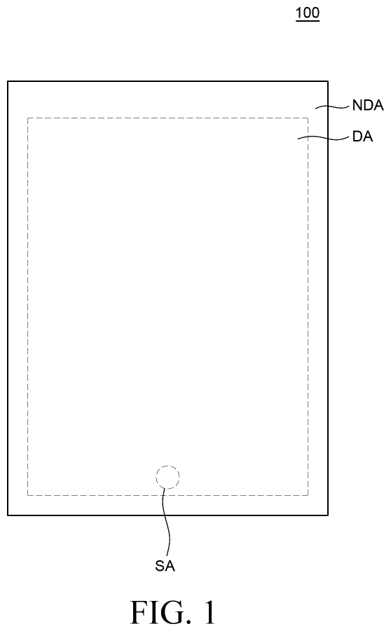

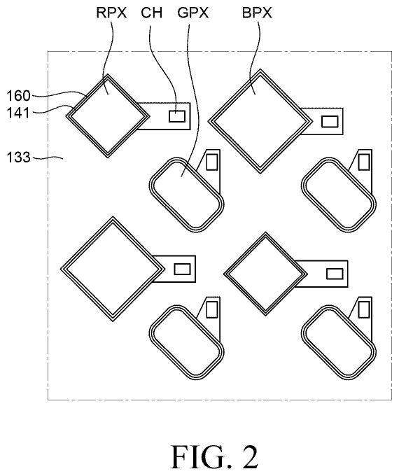

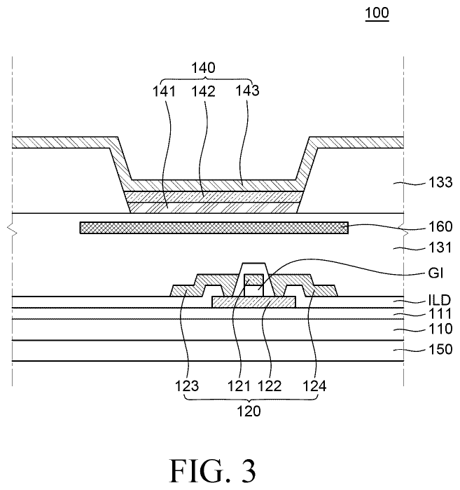

FIG. 1 is a plan view of a display device of one embodiment. FIG. 2 is an enlarged view of a portion of a sensor area of FIG. 1. FIG. 3 is a cross-sectional view of a portion of the sensor area in the display device of one embodiment. Referring to FIGS. 1-3, a display device 100 comprises a substrate 110, a thin film transistor 120, a light emitting diode 140, a sensor part 150, and a heat dissipation panel 160.

The display device 100 comprises areas defined as a display area DA and a non-display area NDA. The display area DA is an area where a plurality of sub pixels RPX, GPX, BPX is disposed and an image is displayed. In the display area DA, sub pixels RPX, GPX, BPX comprising an emission area for displaying an image, and driving elements driving the sub pixels RPX, GPX, BPX may be disposed.

The non-display area NDA surrounds the perimeter of the display area DA. The non-display area NDA is an area where an image is not displayed substantially. In the non-display area NDA, a variety of lines, driver ICs and the like for driving the sub pixels RPX, GPX, BPX and the driving elements that are disposed in the display area DA may be disposed.

In the display area DA, at least one sensor area SA may be formed. In the drawings, one sensor area is disposed on the upper end of the display device 100, but not limited thereto. The sensor area SA may be disposed at a position different from the position of the sensor area SA illustrated in the drawings, depending on the design of a display device or for case of use, and when necessary, two or more sensor areas may be formed.

In the sensor area SA, a sensor for giving a variety of functions to the display device is disposed. For example, in the sensor area SA, an IR sensor, a fingerprint recognition sensor, a proximity sensor, an illuminance sensor, a motion sensor, an iris recognition sensor and the like may be disposed.

As described above, in the display area DA, a plurality of sub pixels RPX, GPX, BPX is arranged. The plurality of sub pixels RPX, GPX, BPX is arranged in a matrix form. Each of the plurality of sub pixels RPX, GPX, BPX is an element for displaying one color. For example, the plurality of sub pixels RPX, GPX, BPX may comprise a red sub pixel RPX, a green sub pixel GPX and a blue sub pixel BPX. For example, the plurality of sub pixels RPX, GPX, BPX may have a disposition structure in which a first column and a second column are arranged alternately. For example, the plurality of sub pixels RPX, GPX, BPX may have a pentile structure where in the first column, the red sub pixel RPX and the blue sub pixel BPX are arranged alternately along a vertical direction, and in the second column, the green sub pixel GPX is arranged along the vertical direction, but not be limited thereto. The shape and disposition of each of the plurality of sub pixels RPX, GPX, BPX may vary depending on a design structure.

Hereinafter, each of the components of the display device 100 is specifically described, with reference to FIG. 3.

The substrate 110 is a substrate for supporting a variety of elements constituting the display device 100. For example, the substrate 110 may be a glass substrate or a plastic substrate. For example, the plastic substrate may be formed of a material selected from polyimide, polyethersulfone, polyethylene terephthalate and polycarbonate, but not limited thereto.

A substrate buffer layer 111 may be disposed on the upper surface of the substrate 110 to prevent the infiltration of oxygen or moisture. The substrate buffer layer 111 may block the flow of hydrogen and the like included in the substrate 110 into a thin film transistor 120 during a deposition process for forming the thin film transistor 120. The substrate buffer layer 111 may have a single-layer structure, and when necessary, a multi-layer structure. For example, the substrate buffer layer 111 may be formed of an inorganic material such as silicon nitride (SiNx), silicon oxide (SiOx), silicon oxynitride (SiON) and the like, but not limited thereto.

The thin film transistor 120 is provided on the substrate 110. The thin film transistor 120 may be disposed to correspond to the plurality of sub pixels RPX, GPX, BPX. The thin film transistor 120 comprises an active layer 121, a gate electrode 122, a source electrode 123 and a drain electrode 124.

The active layer 121 is disposed on the upper surface of the substrate 110, and a gate insulation layer GI for insulating the active layer 121 and the gate electrode 122 is disposed on the active layer 121. Additionally, an interlayer insulation layer ILD for insulating the gate electrode 122 and the source electrode 123 and the drain electrode 124 is disposed on the substrate 110 and the gate electrode 122. On the interlayer insulation layer IDL, the source electrode 123 and the drain electrode 124 respectively contacting the active layer 121 are formed.

A planarization layer 131 is disposed on the thin film transistor 120. The planarization layer 131 planarizes the upper portion of the thin film transistor 120. The planarization layer 131 may comprise a contact hole CH for electrically connecting the thin film transistor 120 and the light emitting diode 140.

The light emitting diode 140 is disposed on the planarization layer 131. The light emitting diode 140 comprises a first electrode 141, an emission layer 142 and a second electrode 143. The light emitting diode 140 may be disposed to correspond to each of the plurality of sub pixels RPX, GPX, BPX.

The first electrode 141 is disposed on the planarization layer 131. The first electrode 141 may be disposed to correspond to each of the plurality of sub pixels RPX, GPX, BPX. The first electrode 141 is formed separately to correspond to each of the red sub pixel RPX, the green sub pixel GPX and the blue sub pixel BPX. The first electrode 141 of the light emitting diode 140 electrically connects to the source electrode 123 or the drain electrode 124 of the thin film transistor 120 corresponding to each of the plurality of sub pixels RPX, GPX, BPX, through the contact hole CH.

The first electrode 141, as a component for providing a hole to the emission layer 142, is formed of a conductive material of high work function. The first electrode 141 may be a transparent conductive layer formed of transparent conductive oxide (TCO). For example, the first electrode 141 may be formed of one or more sorts selected from transparent conductive oxide such as indium-tin-oxide (ITO), indium-zinc-oxide (IZO), indium-tin-zinc oxide (ITZO), tin oxide (SnO₂), zinc oxide (ZnO), indium-copper-oxide (ICO) and aluminum:zinc oxide (Al:ZnO, AZO), but not limited thereto.

In the case where the display device 100 is configured based on the top-emission method, the first electrode 141 may have a structure in which a layer formed of transparent conductive oxide, and a reflective layer formed of a metallic material are stacked. The reflective layer may be formed of a metallic material of high reflectance so that light emitted from the emission layer 142 may be output upward.

A bank 133 is disposed on the first electrode 141 and the planarization layer 131. The bank 133 is formed at boundaries among the plurality of sub pixels RPX, GPX, BPX and divides the areas of adjacent sub pixels RPX, GPX, BPX. The bank 133 is disposed on the planarization layer 131 in such a way that the bank 133 exposes the first electrode 142. Namely, the bank 133 does not cover the first electrode 142 and is disposed adjacent to the first electrode 142. Accordingly, the bank 133 defines the emission area of the light emitting diode 140 disposed at each sub pixel RPX, GPX, BPX. Additionally, the bank 133 may prevent a color mixture between adjacent sub pixels RPX, GPX, BPX. The bank 133 may be made of an insulation material to insulate each first electrode 141 in the sub pixel RPX, GPX, BPX areas from each other.

An emission layer 132 is disposed on the first electrode 141. The emission layer 142 is a layer where an electron and a hole are coupled to emit light. The emission layer 142 is disposed on the first electrode 141 to correspond to each of the plurality of sub pixels RPX, GPX, BPX. The emission layer 142 may comprise an organic light emitting material emitting light of a color corresponding to each of the plurality of sub pixels RPX, GPX, BPX but not be limited thereto, and when necessary, the emission layer 142 may be selectively formed entirely across the plurality of sub pixels RPX, GPX, BPX. At this time, the display device 100 may further comprise a color filter.

The second electrode 143 is disposed on the emission layer 142. The second electrode 143 may be formed of a metallic material of low work function to provide an electron to the emission layer 142 smoothly. For example, the second electrode 143 may be formed of a metallic material selected from calcium (Ca), barium (Ba), aluminum (Al), silver (Ag) and an alloy comprising one or more sorts thereof, but not limited thereto.

The second electrode 143 is formed on the emission layer 142 and the bank 133 in the form of a single layer without being patterned for each of the plurality of sub pixels RPX, GPX, BPX. That is, the second electrode 143 may be shaped into a continuous single layer, without separating for each of the red sub pixel RPX, the green sub pixel GPX and the blue sub pixel BPX. In the case where the display device 100 is driven based on the top emission method, the second electrode 143 may be formed to be very thin and substantially transparent.

To improve emission efficiency, light emitting diode 140 may further comprise a hole injection layer, a hole transport layer, an electron transport layer, an electron injection layer and the like. For example, the hole injection layer and the hole transport layer may be disposed between the first electrode 141 and the emission layer 142, and the electron transport layer and the electron injection layer may be disposed between the emission layer 142 and the second electrode 143.

An encapsulation layer may be disposed on the second electrode 143 to minimize the degradation of the light emitting diode 140, caused by moisture or oxygen. For example, the encapsulation layer may have a triple structure where a first inorganic encapsulation layer, an organic encapsulation layer, and a second inorganic encapsulation layer are stacked, but not be limited thereto.

In the sensor area SA, a sensor part 150 is disposed on the back surface of the substrate 110. The sensor part 150 may comprise Tx electrodes connecting to a Tx driver and Rx electrodes connecting to an Rx driver, and a sensor capacitor may be provided at portions where the Tx electrodes cross the Rx electrodes. Accordingly, the Tx driver may provide a sensor driving signal to the Tx electrodes, and the Rx driver may embody a sensing function in such a way that the Rx driver receives a change in the amounts of charge the sensor capacitor, based on a sensor driving signal.

As described above, in the sensor part 150, a plurality of Tx and Rx lines and drivers are integrated in one circuit, generating heat at a time of operation. The heat generated from the sensor part 150 is transferred to the light emitting diode 140 and degrades the light emitting diode 150. For example, under temperature conditions of 140° C., the emission efficiency of a red light emitting diode may decrease up to 9% from 100%, the emission efficiency of a green light emitting diode may decrease up to 3% from 100%, and the emission efficiency of a blue light emitting diode may decrease up to 5% from 100%.

To prevent this from happening, the display device 100 of one embodiment is provided with a heat dissipation panel 160. The heat dissipation panel 160 is disposed to overlap the first electrode 141. The heat dissipation panel 160 is disposed in the planarization layer 131. That is, the heat dissipation panel 160 may be disposed in such a way that the heat dissipation panel 160 is completely surrounded by the planarization layer 131. Accordingly, the front surface of the heat dissipation panel 160 contacts the planarization layer 131.

Since the heat dissipation panel 160, as described above, is disposed to overlap the first electrode 141, heat generated from the sensor part 150 may be blocked from being transferred to the light emitting diode 140, preventing damage to the light emitting diode 140, caused by the heat.

The heat dissipation panel 160 may be formed of a material of high thermal conductivity. For example, the heat dissipation panel 160 may comprise one or more sorts of materials selected from graphite, aluminum, copper, and a carbon nanotube. Accordingly, heat generated from the sensor part 150 is evenly dispersed, preventing the degradation of the light emitting diode 140 effectively.

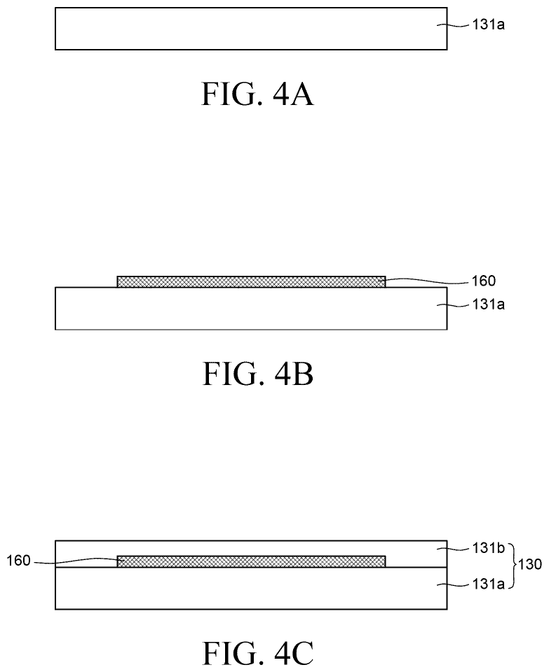

Hereinafter, the process of forming the heat dissipation panel 160 in the planarization layer 131 is described with reference to FIGS. 4A-4C. FIGS. 4A-4C are views for describing a process of forming a heat dissipation panel in the display device of one embodiment. In FIGS. 4A, 4B and 4C, the other components are omitted except for the planarization layer 150 and the heat dissipation panel 160 for convenience of description.

First, a lower planarization layer 131a is formed. The lower planarization layer 131a is disposed at a position where a heat dissipation panel 160 is to be disposed. The lower planarization layer 131a may be formed in such a way that an organic material is applied and cured, but not limited thereto.

Then the heat dissipation panel 160 is formed on the lower planarization layer 131a. The heat dissipation panel, as described above, may be formed in such a way that a material of high thermal conductivity such as graphite or copper and the like is deposited, but not limited thereto.

Then an upper planarization layer 131b is formed to cover the upper surface and the lateral surface of the heat dissipation panel 160. Like the lower planarization layer 131a, the upper planarization layer 131b may be formed in such a way that an organic material is applied and cured.

In the process described above, the heat dissipation panel 160 may be formed to be disposed in the planarization layer 131.

Referring back to FIGS. 2 and 3, the heat dissipation panel 160 may be disposed to correspond to the first electrode 141, and formed to have a width greater than the width of the first electrode 141. At this time, the transfer of heat generated from the heat dissipation panel 160 to the light emitting diode 140 may be suppressed further.

As describe above, the heat dissipation panel 160 is formed of a material of high thermal conductivity such as graphite or copper and the like, and electrically conductive. To prevent the occurrence of a short between the heat dissipation panel 160 and the first electrode 160, the heat dissipation panel 160 and the first electrode 160 are insulated by the upper planarization layer 131b, and the heat dissipation panel 160 is disposed not to overlap the contact hole CH. Accordingly, the heat generated from the sensor part 150 may be blocked without affecting the electrical properties of the light emitting diode 140.

In the display device 100 of one embodiment, although a circuit is highly integrated in the sensor part 150, the heat dissipation panel 160, which is disposed in the planarization layer 131 to overlap the first electrode 160, may block the transfer of heat generated from the sensor part 150 to the light emitting diode 140. Accordingly, damage to the light emitting diode 140, caused by the generation of heat, may be suppressed, and deterioration in diode properties of the light emitting diode 140 may be prevented.

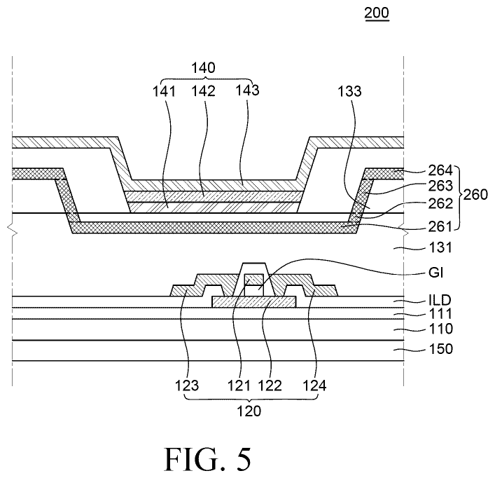

FIG. 5 is a cross-sectional view of a sensor area in a display device of another embodiment. A display device 200 of FIG. 5 comprises a substrate 110, a thin film transistor 120, a light emitting diode 140, a sensor part 150 and a heat dissipation panel 260. The display device 200 illustrated in FIG. 5 is substantially the same as the display device 100 illustrated in FIGS. 1-4 except for the structure of the heat dissipation panel 260. Accordingly, the common components of the display devices are not described.

In the display device 200, the heat dissipation panel 260 comprises a first portion 261, a second portion 262, a third portion 263 and a fourth portion 264.

The first portion 261 is disposed in the planarization layer 131, in parallel with the first electrode 141. That is, the first portion 261 is disposed in the planarization layer 131, in parallel with the lower surface of the first electrode 141. The first portion 261 may be formed to have a width greater than that of the first electrode 141. Accordingly, the first portion 261 may block heat generated from the sensor part 150 effectively.

The second portion 262 is a portion that bends from the end of the first portion 261, in the planarization layer 131. The second portion 262 bends from the end of the first portion 261 toward the upper surface of the planarization layer 131 and has an inclination surface. Accordingly, the second portion 262 is not disposed in parallel with the lower surface of the first electrode 141.

The third portion 263 extends from the second portion 262 placed in the planarization layer 131. The third portion 263 is disposed in the bank 133 disposed on the planarization layer 131. That is, the third portion 263 extends from the end of the second portion 262 placed in the planarization layer 131 and is disposed in the bank 133. Accordingly, the third portion 263 may have an inclination surface of a gradient the same as that of the second portion 262.

The fourth portion 264 extends from the third portion 263. Specifically, the fourth portion 264 extends from the end of the third portion 263, in the bank 133. The fourth portion 264 is disposed in the bank 133. The fourth portion 264 may be disposed in the bank 133, in parallel with the upper surface of the planarization layer 131.

In this embodiment, a part of the heat dissipation panel 260 is placed in the planarization layer 131, and the rest of the heat dissipation panel 260 is placed in the bank 133. At this time, the front surface of the heat dissipation panel 260 is disposed to be surrounded by the planarization layer 131 and the bank 133 and not to contact the first electrode 141. In the case where the heat dissipation panel 260 is disposed to extend from the planarization layer 131 to the bank 133, the cross-sectional area of the heat dissipation panel 260 may expand to improve the heat dissipation properties of the heat dissipation panel 260. Specifically, in Fourier's law of conduction, thermal conductance is proportional to a surface area, a difference in temperature, and thermal conductance of each material itself, and inversely proportional to thickness (length). In the case where heat is transferred from the sensor part 150 to the heat dissipation panel 260, as the thermal conductivity and cross-sectional area of a material increase further, heat is dispersed better, and as a result, there is a little difference in the temperatures inside and outside the heat dissipation panel 260. Thus, an increase in the cross-sectional area of the heat dissipation panel 260 or a material of high thermal conductivity may lead to improvement in heat dissipation properties.

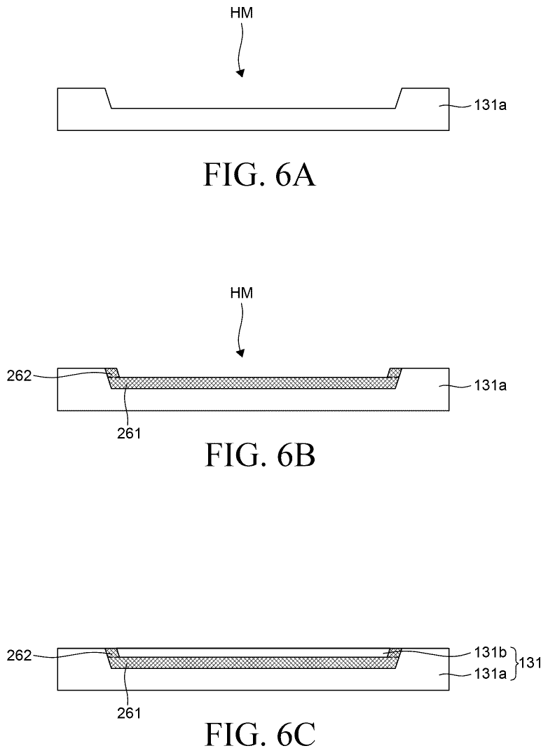

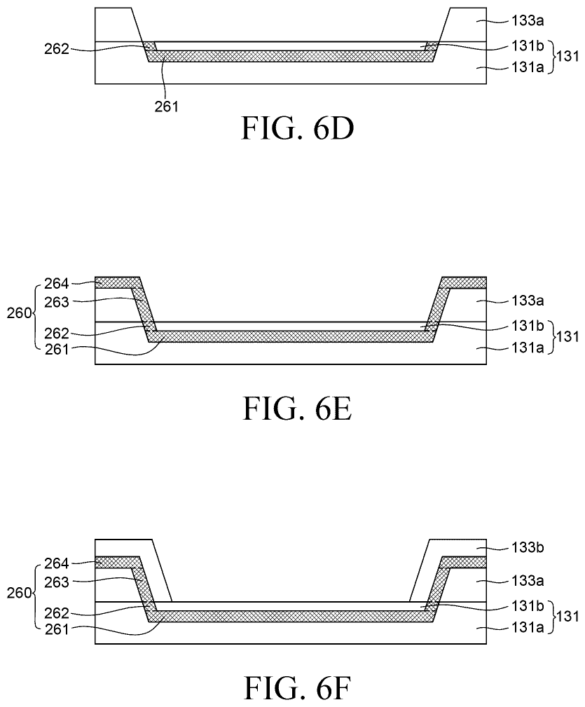

Hereinafter, the process of forming the heat dissipation panel 260 in the planarization layer 131 and the bank 133 is described with reference to FIGS. 6A-6F. FIGS. 6A-6F are views for describing a process of forming a heat dissipation panel in the display device of another embodiment. In FIGS. 6A-6F, the other components are omitted except for the planarization layer 131, the bank 133 and the heat dissipation panel 260 for convenience of description.

First, a lower planarization layer 131a is formed. The lower planarization layer 131a is formed in such a way that an organic material is applied and cured, and then an area corresponding to a light emitting diode 140 is partially etched and provided with a groove HM. Accordingly, in the case of a lower planarization layer 131a, the area corresponding to the light emitting diode 140 may be thin, and an outer portion of the area corresponding to the light emitting diode 140 may be thick.

Then a material of high thermal conductivity such as graphite or copper and the like is deposited on the lower planarization layer 131a, to form a first portion 261 and a second portion 262 of the heat dissipation panel 260. The first portion 261 and the second portion 262 are deposited along the groove HM formed at the lower planarization layer 131a. Accordingly, the first portion 261 deposited on the lower planarization layer 131a that is thin and has a constant thickness is parallel with the lower surface of the first electrode 141, and the second portion 262 has an inclination surface.

Then an upper planarization layer 131b is formed on the first portion 261 and the second portion 262 of the heat dissipation panel 260. The upper planarization layer 131b is formed on the first portion 261 and the second portion 262 of the heat dissipation panel 260 to fill the groove HM formed at the lower planarization layer 131a. The upper planarization layer 131b may be formed in such a way that an organic material is applied and cured on the first portion 261 and the second portion 262.

Then a primary bank 133a is formed on a planarization layer 131. The primary bank 133a is formed on an area that is thick at the lower planarization layer 131a. The primary bank 133a may be formed in such a way that an organic insulation material is applied and cured and then patterned.

Then a material such as graphite or copper and the like is deposited on the primary bank 133a's lateral surface that inclines and the primary bank 133a's upper surface to form a third portion 263 and a fourth portion 264 of the heat dissipation panel 260. The third portion 263 is formed on the primary bank 133a's lateral surface that inclines and has an inclination surface. Then fourth portion 264 is formed planarly on the upper surface of the primary bank 133a. At this time, the third portion 263 may be formed to connect to the second portion 262 formed in the planarization layer 131.

Then a secondary bank 133b is formed on the third portion 263 and the fourth portion 264 of the heat dissipation panel 260. The secondary bank 133b is formed to cover the upper portions of the third portion 263 and the fourth portion 264. The secondary bank 133b may be formed in such a way that an organic insulation material is applied and cured and the patterned.

In the process described above, a part of the heat dissipation panel 260 is placed in the planarization layer 131, and the rest of the heat dissipation panel 260 is placed in the bank 133. At this time, in the display device 200, the cross-sectional area of the heat dissipation panel 260 is greater than that of the heat dissipation panel 260 in the display device 100 illustrated in FIGS. 1-4, securing more excellent heat dissipation efficiency. Accordingly, heat generated from the sensor part 150 may be blocked effectively, and damage to the light emitting diode 140, caused by the heat, may be prevented. Thus, more excellent display quality may be secured.

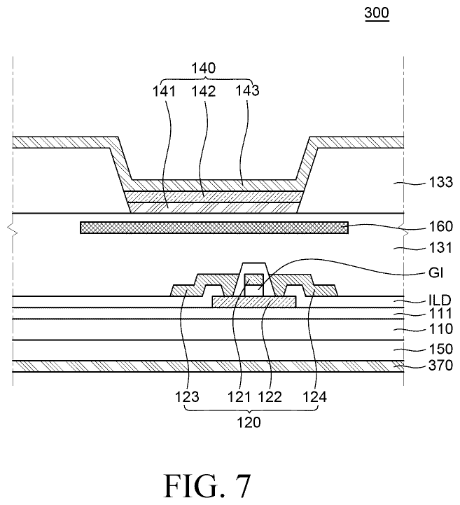

FIG. 7 is a cross-sectional view of a sensor area in a display device of another embodiment. Referring to FIG. 7, a display device 300 comprises a substrate 110, a thin film transistor 120, a light emitting diode 140, a sensor part 150, a heat dissipation panel 260, and an auxiliary heat dissipation panel 370. The display device 300 illustrated in FIG. 7 is substantially the same as the display device 100 illustrated in FIGS. 1-4 except that the display device 300 further comprises an auxiliary heat dissipation panel 370. Accordingly, the common components of the display devices are not described.

The display device 300 illustrated in FIG. 7, comprises an auxiliary heat dissipation panel 370. The auxiliary heat dissipation panel 170 is disposed on the back surface of the sensor part 150. The auxiliary heat dissipation panel 370 may be disposed to correspond to the entire back surface of the sensor part 150. The auxiliary heat dissipation panel 370 may be disposed to contact the back surface of the sensor part 150.

In the case where the auxiliary heat dissipation panel 370 is further provided on the back surface of the sensor part 150 as described above, the conduction of heat generated from the sensor part 150 to the auxiliary heat dissipation panel 370 and the effect of the heat on the light emitting diode 140 may be suppressed further. Accordingly, although a highly integrated circuit is provided in the sensor part 150, damage to the light emitting diode 140, caused by the generation of heat, and the degradation of the light emitting diode 140 at high temperature may be minimized effectively, securing high reliability.

Like the heat dissipation panel 160, the auxiliary heat dissipation panel 370 may comprise one or more sorts of materials selected from graphite, aluminum, copper and a carbon nanotube.

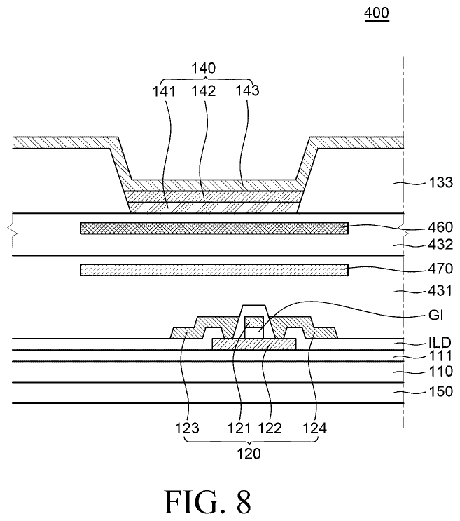

FIG. 8 is a cross-sectional view of a sensor area in a display device of another embodiment. Referring to FIG. 8, a display device 400 comprises a substrate 110, a thin film transistor 120, a first planarization layer 431, a second planarization layer 432, a light emitting diode 140, a sensor part 150, a heat dissipation panel 460, and an auxiliary heat dissipation panel 470. The display device 400 illustrated in FIG. 8 is substantially the same as the display device 100 illustrated in FIGS. 1-4 except that the display device 400 further comprises a double-layer planarization layer 431, 432 and an auxiliary heat dissipation panel 470. Accordingly, the common components of the display devices are not described.

Referring to FIG. 8, the first planarization layer 431 is disposed on the thin film transistor 120. The first planarization layer 431 planarizes the upper portion of the thin film transistor 120.

The second planarization layer 432 is disposed on the first planarization layer 431. The second planarization layer 432 provides a planar surface.

The light emitting diode 140 is disposed on the second planarization layer 432. The first planarization layer 431 and the second planarization layer 432 may comprise a contact hole for connecting the thin film transistor 120 and the light emitting diode 140 electrically. Accordingly, the light emitting diode 140 on the second planarization layer 432 may electrically connect to the thin film transistor 120 through the contact hole.

In the display device 400 of this embodiment, the heat dissipation panel 460 is disposed in the second planarization layer 432, in such a way that the heat dissipation panel 460 overlaps a first electrode 141 of the light emitting diode 140. That is, the heat dissipation panel 460 may be disposed to be surrounded by the second planarization layer 432 completely. Accordingly, the front surface of the heat dissipation panel 460 is disposed to be surrounded by the second planarization layer 432. As a result, the front surface of the heat dissipation panel 460 contacts the second planarization layer 432. At this time, the heat dissipation panel 460 is formed not to contact the first electrode 141 and the contact hole to prevent a short.

In this embodiment, the auxiliary heat dissipation panel 470 is disposed in the first planarization layer 431. The auxiliary heat dissipation panel 470 may be disposed in the first planarization layer 431 in such a way that the auxiliary heat dissipation panel 470 overlaps the first electrode 141 and the heat dissipation panel 460. That is, the front surface of the auxiliary heat dissipation panel 470 is disposed to be surrounded by the first planarization layer 431 completely. Accordingly, the front surface of the auxiliary heat dissipation panel 470 is disposed to contact the first planarization layer 431. At this time, the auxiliary heat dissipation panel 470 is formed not to contact the contact hole electrically connecting the thin film transistor 120 and the light emitting diode 140, to prevent a short with the first electrode 141.

The auxiliary heat dissipation panel 470 may be formed in the first planarization layer 431 in the same way as for the way described with reference to FIGS. 4A-4C. Accordingly, description in relation to this is omitted.

In the display device 400 of this embodiment, the planarization layer has a double-layer structure in which the first planarization layer 431 and the second planarization layer 432 are stacked, and the auxiliary heat dissipation panel 470 is disposed in the first planarization layer 431, while the heat dissipation panel 460 is disposed in the second planarization layer 432. In the structure, the planarization layer 431, 432 may be thick, and the auxiliary heat dissipation panel 470 and the heat dissipation panel 460 may effectively block heat generated from the sensor part 150. Thus, damage to the light emitting diode 14, caused by the generation of heat, is suppressed, and deterioration in the diode properties of the light emitting diode 140 is prevented.

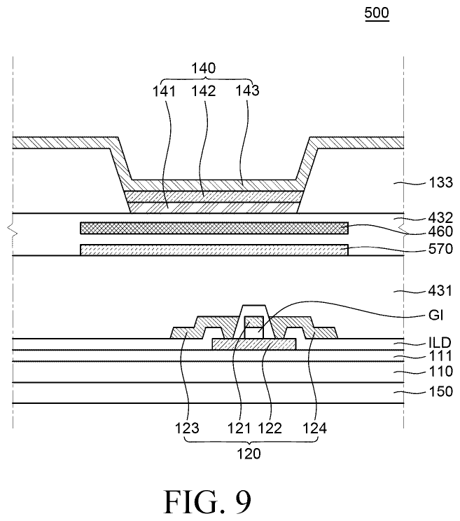

FIG. 9 is a cross-sectional view of a sensor area in a display device of yet another embodiment.

Referring to FIG. 9, a display device 500 comprises a substrate 110, a thin film transistor 120, a first planarization layer 431, a second planarization layer 432, a light emitting diode 140, a sensor part 150, a heat dissipation panel 460 and an auxiliary heat dissipation panel 570. The display device 500 illustrated in FIG. 9 is substantially the same as the display device 400 illustrated in FIG. 8 except for the disposition structure of the auxiliary heat dissipation panel. Accordingly, the common components of the display devices are not described.

Referring to FIG. 9, the auxiliary heat dissipation panel 570 is disposed to overlap the first electrode 141 and the heat dissipation panel 460. The auxiliary heat dissipation panel 570 is disposed between the first planarization layer 431 and the second planarization layer 432. The auxiliary heat dissipation panel 570 is disposed on the upper surface of the first planarization layer 431. The second planarization layer 432 is disposed on the first planarization layer 431 to cover the auxiliary heat dissipation panel 570. Accordingly, the auxiliary heat dissipation panel 570 may be structured to be surrounded by the first planarization layer 431 and the second planarization layer 432 completely.

In the case where a planarization layer has a double-layer structure where a first planarization layer 431 and a second planarization layer 432 are stacked, and is provided with an auxiliary heat dissipation panel 570 and a heat dissipation panel 460 as described above, the generation of heat from the sensor part 150 may be blocked effectively, thereby suppressing damage to the light emitting diode 140 and preventing deterioration in the diode properties of the light emitting diode 140, caused by the generation of heat.

Additionally, in the case where the auxiliary heat dissipation panel 570 is disposed on the first planarization layer 431, the manufacturing of the display device in FIG. 9 may be simplified further than that of the display device in FIG. 8. Specifically, as illustrated in FIGS. 4A-4C, the first planarization layer 431 is formed in a single process, without being formed in such a way that the upper portion and the lower portion of the first planarization layer 431 are formed in a separate manner, and then the auxiliary heat dissipation panel 570 is deposited, and the second planarization layer 432 and the heat dissipation panel 460 are formed, thereby securing case of processing.

Hereinafter, the above effects produced by the subject matter of the present disclosure are specifically described with reference to embodiments. However, the embodiments are provided as examples and are not intended to limit the scope of the present disclosure.

### Experimental Example 1

An embodiment sample was formed by depositing graphite in the planarization layer and forming a heat dissipation panel, and an experimental sample without a heat dissipation panel was formed to estimate their heat dissipation properties. The heat dissipation properties were estimated by measuring a change in temperature based on a thermal image camera analysis under the conditions shown in Table 1, and results of the estimation are shown in Table 1 hereinafter. The change in temperature is a difference between room temperature prior to measurement and temperature after the application of heat from a heat generating object.

TABLE 1

Room temperature

| | Measurement within | Measurement within |
|---|---|---|
| | 10 seconds | 10-20 seconds |
| Comparative | Δ4.7° C. | Δ0.7° C. |
| example | | |
| Embodiment | Δ0.9° C. | Δ0.1° C. |

Referring to Table 1, in the embodiment with a heat dissipation panel deposited, after heat is applied from the heat generating object, the change in temperature is 0.9° C. within 10 seconds, and 0.1° C. within 10-20 seconds, causing almost no change. Accordingly, in the case where the heat dissipation panel is deposited, heat generated from a heat generating object is blocked, so that temperature returns to temperature similar to room temperature rapidly within 10 seconds.

On the contrary, in the comparative example with no heat dissipation panel deposited, the change in temperature is 4.7° C. within 10 seconds, which is greater than that of the embodiment, showing that heat from the heat generating object is not blocked. Additionally, in the comparative example, the change in temperature is 0.7° C. within 10-20 seconds, showing that temperature of the comparative example returns to room temperature slower than that of the embodiment.

As a result, in the case where a heat dissipation panel is provided in the planarization layer, the generation of heat may be blocked, and the degradation of a light emitting diode may be prevented. Thus, deterioration in the properties of the light emitting diode may be prevented, making it possible to provide a highly reliable display device.

The exemplary embodiments of the present disclosure can also be described as follows:

According to an aspect of the present disclosure, there is provided a display device. THE display device provided with at least one sensor area comprises a substrate; a thin film transistor disposed on the substrate; a planarization layer disposed to cover the thin film transistor; a light emitting diode disposed on the planarization layer, and configured to comprise a first electrode, an emission layer disposed on the first electrode and a second electrode disposed on the emission layer; a bank configured to expose at least part of the first electrode and disposed on the planarization layer; a sensor part disposed on a back surface of the substrate in the sensor area; and a heat dissipation panel disposed between the substrate and the first electrode.

The heat dissipation panel may be disposed to overlap the first electrode.

At least part of the heat dissipation panel may be disposed in the planarization layer.

The heat dissipation panel may be structured to be surrounded by the planarization layer completely.

The heat dissipation panel may comprise a first portion disposed in the planarization layer in parallel with a lower surface of the first electrode; and a second portion bent from an end of the first portion, configured to have an inclination surface and disposed in the planarization layer, a third portion extended from the second portion, configured to have an inclination surface and disposed in the bank; and a fourth portion extended from the third portion and disposed in the bank in parallel with an upper surface of the planarization layer.

The display device may further comprise an auxiliary heat dissipation panel disposed under the heat dissipation panel.

The auxiliary heat dissipation panel may be disposed on a back surface of the sensor part.

The planarization layer may comprise a first planarization layer disposed to cover the thin film transistor; a second planarization layer disposed on the first planarization layer, wherein the light emitting diode may be disposed on the second planarization layer, and the heat dissipation panel may be disposed in the second planarization layer.

The auxiliary heat dissipation panel may be disposed in the first planarization layer and structured to be surrounded by the first planarization layer completely.

The auxiliary heat dissipation panel may be disposed on the first planarization layer, and the second planarization layer may be disposed to cover the auxiliary heat dissipation panel.

The planarization layer may comprise a contact hole connecting the thin film transistor and the first electrode electrically, and the heat dissipation panel may be disposed not to overlap the contact hole.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate having thereon at least one sensor area, the substrate having a back surface;
a thin film transistor on the substrate;
a planarization layer disposed to cover the thin film transistor;
a light emitting diode on the planarization layer, the light emitting diode including a first electrode, an emission layer on the first electrode, and a second electrode on the emission layer;
a bank on the planarization layer, the bank exposing at least part of the first electrode;
a sensor part on the back surface of the substrate in the at least one sensor area; and
a heat dissipation panel disposed between the substrate and the first electrode.

2. The display device of claim 1, wherein the heat dissipation panel is disposed to overlap the first electrode from a plan view.

3. The display device of claim 2, wherein at least part of the heat dissipation panel is disposed in the planarization layer.

4. The display device of claim 3, wherein the heat dissipation panel is completely surrounded by the planarization layer.

5. The display device of claim 3, wherein the heat dissipation panel is adjacent to the planarization layer and overlaps with the planarization layer from a plan view.

6. The display device of claim 1, the heat dissipation panel, comprising:
a first portion disposed in the planarization layer in parallel with a lower surface of the first electrode; and
a second portion bent from an end of the first portion, configured to have an inclination surface and disposed in the planarization layer,
a third portion extended from the second portion, configured to have an inclination surface and disposed in the bank; and
a fourth portion extended from the third portion and disposed in the bank in parallel with an upper surface of the planarization layer.

7. The display device of claim 3, the heat dissipation panel, comprising:
a first portion disposed in the planarization layer in parallel with a lower surface of the first electrode; and
a second portion bent from an end of the first portion, configured to have an inclination surface and disposed in the planarization layer,
a third portion extended from the second portion, configured to have an inclination surface and disposed in the bank; and
a fourth portion extended from the third portion and disposed in the bank in parallel with an upper surface of the planarization layer.

8. The display device of claim 3, wherein the display device further comprises an auxiliary heat dissipation panel disposed under the heat dissipation panel.

9. The display device of claim 8, wherein the auxiliary heat dissipation panel is on a back surface of the sensor part.

10. The display device of claim 8, the planarization layer, comprising:
a first planarization layer disposed to cover the thin film transistor;
a second planarization layer on the first planarization layer,
wherein the light emitting diode is on the second planarization layer, and the heat dissipation panel is disposed in the second planarization layer.

11. The display device of claim 10, wherein the auxiliary heat dissipation panel is disposed in the first planarization layer and is completely surrounded by the first planarization layer.

12. The display device of claim 10, wherein the auxiliary heat dissipation panel is on the first planarization layer, and the second planarization layer is disposed to cover the auxiliary heat dissipation panel.

13. The display device of claim 1, wherein the planarization layer comprises a contact hole connecting the thin film transistor and the first electrode electrically, and the heat dissipation panel is disposed not to overlap the contact hole.
